(19) United States
(12) Patent Application Publication
(10) Pub. No.: US 2021/0305679 A1
(43) Pub. Date: Sep. 30, 2021

(54) Radio-Frequency Arrangement Having a Frontside and a Backside Antenna

(71) Applicant: Fraunhofer-Gesellschaft zur Foerderung der angewandten Forschung e.V., Munich (DE)

(72) Inventor: Peter RAMM, Muenchen (DE)

(21) Appl. No.: 17/208,847

(22) Filed: Mar. 22, 2021

(30) Foreign Application Priority Data
Mar. 26, 2020 (DE) 102020203970.4

(51) Int. Cl. H01Q 1/22; H05K 1/03

(52) U.S. Cl. CPC H01Q 1/2283; H05K 1/0393; H01Q 1/2208

(57) ABSTRACT

A radio-frequency arrangement is described. The radio-frequency arrangement has a radio-frequency device having a radio-frequency circuit. Additionally, the radio-frequency arrangement has a flexible substrate having at least two antennas, wherein the radio-frequency circuit is coupled to the at least two antennas, and wherein the flexible substrate is arranged at least partly around the radio-frequency device, wherein at least one first antenna of the at least two antennas is arranged adjacent to a first side of the radio-frequency device and at least one second antenna of the at least two antennas is arranged adjacent to a second side of the radio-frequency device opposite the first side.

### CROSS-REFERENCE TO RELATED APPLICATION

This application claims priority from German Application No. 102020203970.4, which was filed on Mar. 26, 2020, and is incorporated herein by reference in its entirety.

### BACKGROUND OF THE INVENTION

Embodiments of the present invention relate to a radio-frequency arrangement and, in particular, to a radio-frequency arrangement having a frontside and a backside antenna. Further embodiments relate to a method for manufacturing a radio-frequency arrangement.

Conventionally, when setting up systems of mobile communication, the electrical connection of the backside antenna structures is realized via vertical connections (so-called copper pillars) within the printed circuit board (PCB), as is exemplarily shown in FIG. 1.

In detail, FIG. 1 shows a cross-sectional view of an antenna board 10 having backside antenna structures 12 which are connected via so-called copper pillars 14 [1].

Such a radio-frequency circuit (radio-frequency integrated circuit—RFIC) having backside antenna structures which are electrically linked via vertical connections, however, is relatively expensive and complicated in manufacturing.

Thus, the object underlying the present invention is providing a cheaper and easier-to-manufacture radio-frequency circuit having backside antenna structures.

### SUMMARY

In accordance with an embodiment, a radio-frequency arrangement may have: a radio-frequency device having a radio-frequency circuit, and a flexible substrate having at least two antennas, wherein the radio-frequency circuit is coupled to the at least two antennas, and wherein the flexible substrate is arranged at least partly around the radio-frequency device, wherein at least one first antenna of the at least two antennas is arranged adjacent to a first side of the radio-frequency device and at least one second antenna of the at least two antennas is arranged adjacent to a second side of the radio-frequency device opposite the first side.

Another embodiment may have a participant of a mobile radio communication system, wherein the participant has an inventive radio-frequency arrangement as mentioned above.

According to another embodiment, a method for manufacturing a radio-frequency arrangement may have the steps of: providing a radio-frequency device having a radio-frequency circuit, providing a flexible substrate having at least two antennas, arranging the flexible substrate at least partly around the radio-frequency device so that at least one first antenna of the at least two antennas is arranged adjacent to a first side of the radio-frequency device and at least one second antenna of the at least two antennas is arranged adjacent to a second side of the radio-frequency device opposite the first side, and connecting at least one terminal of the radio-frequency device coupled to the radio-frequency circuit, to the at least two antennas.

Embodiments provide a radio-frequency arrangement. The radio-frequency arrangement comprises a radio-frequency device having a radio-frequency circuit. Additionally, the radio-frequency arrangement comprises a flexible substrate having at least two antennas, wherein the radio-frequency circuit is coupled to the at least two antennas, and wherein [so that, for example] the flexible substrate is arranged at least partly around the radio-frequency device, wherein at least one first antenna of the at least two antennas is arranged adjacent to a first side [like first surface] of the radio-frequency device and at least one second antenna of the at least two antennas is arranged adjacent to a second side [like second surface] of the radio-frequency device opposite the first side.

In embodiments, the flexible substrate is bent at least partly around the radio-frequency device.

In embodiments, a first portion of the flexible substrate which comprises the at least one first antenna, is arranged adjacent to the first side of the radio-frequency device, wherein a second portion of the flexible substrate which comprises the at least one second antenna, is arranged adjacent to the second side of the radio-frequency device.

In embodiments, a first portion of the flexible substrate which comprises the at least one first antenna, abuts on the first side of the radio-frequency device, wherein a second portion of the flexible substrate which comprises the at least one second antenna, abuts on the second side of the radio-frequency device.

In embodiments, the at least two antennas can be arranged in different planes of the radio-frequency arrangement.

In embodiments, the first portion of the flexible substrate and the second portion of the flexible substrate can be arranged in different planes of the radio-frequency arrangement.

In embodiments, the radio-frequency device can be arranged between the at least two antennas.

In embodiments, the flexible substrate can comprise a metallization, wherein the radio-frequency circuit can be coupled to the at least two antennas via the metallization.

In embodiments, the metallization is arrangement in the same layer plane of the flexible substrate as are the at least two antennas.

In embodiments, the metallization is arrangement in a different layer plane of the flexible substrate than the at least two antennas.

In embodiments, the radio-frequency device comprises at least one terminal coupled to the radio-frequency circuit, wherein the at least one terminal is coupled to the metallization of the flexible substrate.

In embodiments, the radio-frequency device is an RFIC (radio-frequency integrated circuit).

Further embodiments provide a mobile radio communication device, the mobile radio communication device comprising a radio-frequency arrangement in accordance with any of the embodiments described before/herein.

Further embodiments provide a method for manufacturing a radio-frequency arrangement. The method comprises providing a radio-frequency device having a radio-frequency circuit. Additionally, the method comprises providing a flexible substrate having at least two antennas. Additionally, the method comprises arranging the flexible substrate at least partly around the radio-frequency device so that at least one first antenna of the at least two antennas is arranged adjacent to a first side of the radio-frequency device and at least one second antenna of the at least two antennas is arranged adjacent to a second side of the radio-frequency device opposite the first side. Additionally, the method comprises connecting at least one terminal of the radio-frequency device coupled to the radio-frequency circuit, to the at least two antennas.

In embodiments, when arranging the flexible substrate at least partly around the radio-frequency device, the flexible substrate is bent at least partly around the radio-frequency device.

In embodiments, when arranging the flexible substrate at least partly around the radio-frequency device, a first portion of the flexible substrate which comprises the at least one first antenna, is arranged adjacent to the first side of the radio-frequency device or abuts on the first side of the radio-frequency device, wherein, when arranging the flexible substrate at least partly around the radio-frequency device, a second portion of the flexible substrate which comprises the at least one second antenna, is arranged adjacent to the second side of the radio-frequency device or abuts on the second side of the radio-frequency device.

In embodiments, when connecting at least one terminal of the radio-frequency device coupled to the radio-frequency circuit, to the at least two antennas, the at least one terminal of the radio-frequency device is connected to at least one terminal of the flexible substrate coupled to the at least two antennas.

In embodiments, when connecting at least one terminal of the radio-frequency device coupled to the radio-frequency circuit, to the at least two antennas, an electrically conducting connection is produced between the terminal of the radio-frequency device and the terminal of the flexible substrate.

In embodiments, when providing the flexible substrate, the at least two antennas are produced in the flexible substrate.

In embodiments, when providing the flexible substrate, a metallization connected to the at least two antennas is produced in the flexible substrate.

In embodiments, the metallization is produced in the same layer plane of the flexible substrate as are the at least two antennas.

In embodiments, the metallization is produced in a different layer plane of the flexible substrate than the at least two antennas.

In embodiments, when providing the flexible substrate, a connection is produced between at least one terminal of the flexible substrate and the metallization.

Further embodiments provide an apparatus. The apparatus comprises a radio-frequency circuit device. Additionally, the apparatus comprises at least one electrically conducting connection from the top side of the radio-frequency circuit device to at least one terminal means. Additionally, the apparatus comprises a flexible substrate having antennas in the flexible substrate, which are connected to a metallization in an electrically conducting way, and at least one electrically conducting connection between the terminal means and the metallization, wherein the flexible substrate is arranged around the radio-frequency circuit device such that at least one antenna is located above the radio-frequency circuit device and at least one antenna is located below the radio-frequency circuit device.

Embodiments of the present invention provide a system setup for mobile radio communication devices using radio-frequency circuits (like RFICs) on a flexible substrate having integrated antenna structures for frontside and backside reception and transmission (front side and backside antennas).

Embodiments of the present invention provide a method for manufacturing electronic radio-frequency systems and, in particular, highly integrated so-called systems-in-package for being used in mobile communication.

Embodiments of the present invention realize an electrical connection of at least one radio-frequency circuit to frontside and backside antennas via a specific flexible wiring substrate having integrated antenna structures (frontside and backside antenna).

### BRIEF DESCRIPTION OF THE DRAWINGS

Embodiments of the present invention will be described below in greater detail referring to the appended drawings, in which:

FIG. 1 shows a cross-sectional view of a conventional antenna board having backside antenna structures which are coupled via so-called copper pillars [1];

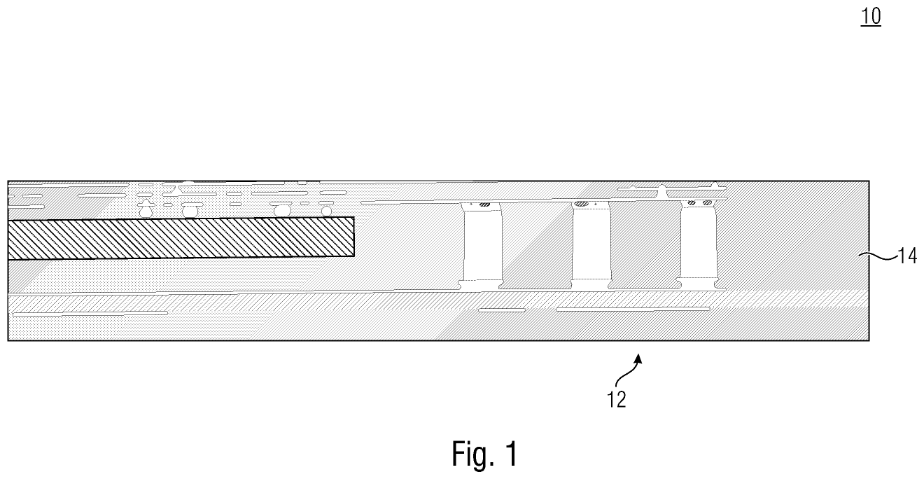

FIG. 2 shows a schematic cross-sectional view of a radio-frequency arrangement in accordance with an embodiment of the present invention;

FIG. 3 shows a schematic cross-sectional view of a radio-frequency arrangement in accordance with another embodiment of the present invention;

FIG. 4 shows a schematic block circuit diagram of a participant 130 of a mobile radio communication system having a radio-frequency arrangement in accordance with an embodiment of the present invention;

FIG. 5 shows a flow chart of a method for manufacturing a radio-frequency arrangement in accordance with an embodiment of the present invention; and

FIG. 6 shows a flow chart of a method for connecting an electrical radio-frequency circuit to an arrangement of antennas in accordance with an embodiment of the present invention.

### DETAILED DESCRIPTION OF THE INVENTION

In the following description of embodiments of the present invention, equal elements or elements of equal effect are provided with equal reference numerals in the figures so that their description is neutrally interchangeable.

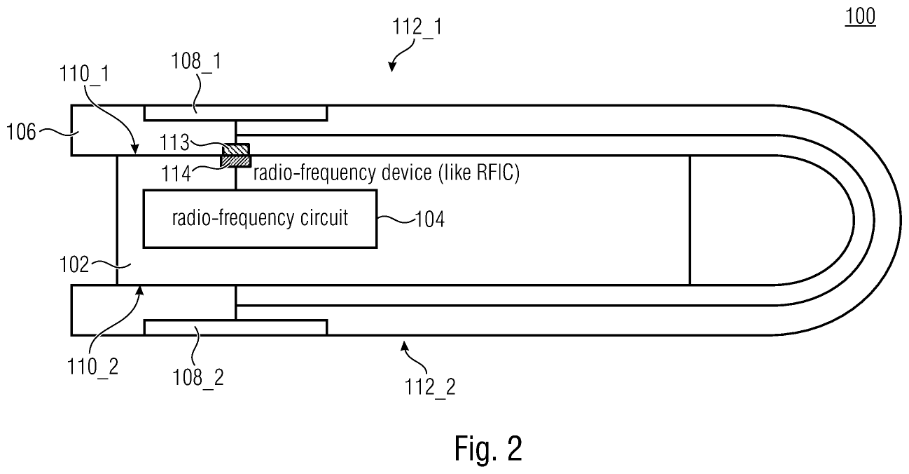

FIG. 2 shows a schematic cross-sectional view of a radio-frequency arrangement (100) in accordance with an embodiment of the present invention. The radio-frequency arrangement 100 comprises a radio-frequency device 102 comprising a radio-frequency circuit 104 and a flexible substrate 106 having at least two antennas 108_1 and 108_2, wherein the radio-frequency circuit 100 is coupled (or connected) to the at least two antennas 108_1 and 108_2, and wherein the flexible substrate 106 is arranged at least partly around the radio-frequency device 102, wherein at least one first antenna 108_1 of the at least two antennas 108_1 and 108_2 is arranged adjacent to a first side 110_1 of the radio-frequency device 102 and at least one second antenna 108_2 of the at least two antennas 108_1 and 108_2 is arranged adjacent to a second side 110_2 of the radio-frequency device opposite the first side 110_1.

In embodiments, the at least one first antenna 108_1 can thus form at least one frontside antenna of the radio-frequency arrangement 100, wherein the at least one second antenna 108_2 can form at least one backside antenna of the radio-frequency arrangement 100.

In order to realize this, the flexible substrate 106, as can be recognized in FIG. 2, can be bent at least partly around the radio-frequency device 102, for example such that a first portion 112_1 of the flexible substrate 106 which comprises the at least one first antenna 108_1, is arranged adjacent to the first side 110_1 of the radio-frequency device 102 or abuts on the first side 110_1 of the radio-frequency device 102, and a second portion 112_2 of the flexible substrate 106 which comprises the at least one second antenna 108_2, is arranged adjacent to the second side 110_2 of the radio-frequency device 102 or abuts on the second side 110_2 of the radio-frequency device 102.

In FIG. 2, the radio-frequency arrangement 100 exemplarily comprises only two antennas 108_1 and 108_2. However, it is to be pointed out that the radio-frequency arrangement 100 can also comprise more than two antennas in embodiments. Thus, the radio-frequency arrangement 100 can comprise up to n antennas, n being a natural number of greater than or equaling two, n 2. Here, at least one first antenna of the n antennas can be arranged adjacent to the first side 110_1 of the radio-frequency device 102, whereas at least one second antenna of the n antennas can be arranged adjacent to the second side 110_2 of the radio-frequency device 102.

The radio-frequency arrangement 100 can, for example, comprise four antennas, wherein at least one first antenna 108_1 of the four antennas, like one, two or three of the four antennas, for example, can be arranged adjacent to the first side 110_1 of the radio-frequency device 102, wherein at least one second antenna 108_2 of the four antennas, like one, two or three of the four antennas, for example, can be arranged adjacent to the second side 110_1 of the radio-frequency device 102.

In embodiments, the radio-frequency device can be a radio-frequency board or RFIC (Radio Frequency Integrated Circuit).

As has already been mentioned, the radio-frequency circuit 104 can be coupled to the at least two antennas 108_1 and 108_2. Coupling here means either a direct connection, like via a line, or an indirect connection, like with a coupling element (like capacitive coupler) connected therebetween.

In embodiments, the radio-frequency circuit 104 can be coupled to the at least two antennas 108_1 and 108_2 via at least one terminal 114 of the radio-frequency device 102 coupled to the radio-frequency circuit.

Optionally, the flexible substrate 106 can comprise at least one terminal 113 coupled (or connected) to the at least two antennas 108_1 and 108_2. In this case, the at least one terminal 114 of the radio-frequency device 102 can be coupled (or connected) to the at least one terminal 113 of the flexible substrate.

The at least one terminal 114 of the radio-frequency device 102 here can be arranged exclusively at a single side of the radio-frequency device 102, like the first side 110_1 of the radio-frequency device 102, as is shown in FIG. 2, or alternatively at the second side 110_2 of the radio-frequency device.

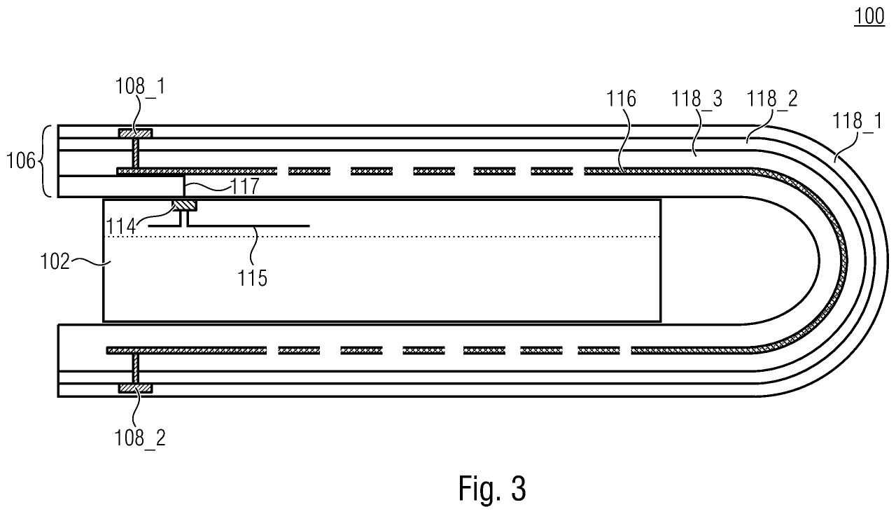

The at least two antennas 108_1 and 108_2 here can be coupled (or connected) to the at least one terminal 114 via a metallization, as is shown in FIG. 3.

FIG. 3 shows a schematic cross-sectional view of a radio-frequency arrangement 100 in accordance with another embodiment of the present invention. Supplementing FIG. 2, the metallization 116 is shown in FIG. 3, via which the at least two antennas 108_1 and 108_2 are coupled (or connected) to the at least one terminal 114 of the radio-frequency device 102.

The metallization 116 here can be arranged in a different plane of the flexible substrate 106 than the at least two antennas 108_1 and 108_2. Exemplarily, the flexible substrate 106, as is shown in FIG. 3, can comprise three planes 118_1, 118_2 and 118_3, wherein the at least two antennas 108_1 and 108_2 can be arranged (or formed) in a first plane 118_1 of the flexible substrate 106, whereas the metallization can be arranged (or formed) in a third plane 118_3 of the flexible substrate 106.

Alternatively, the metallization 116 can also be arranged (or formed) in the same plane of the flexible substrate 106 as are the at least two antennas 108_1 and 108_2, like in the first plane 118_1 of the flexible substrate 106, for example. In this case, the flexible substrate can comprise also only a single plane.

In other words, FIG. 3 shows a schematic block circuit diagram of an apparatus 100 in accordance with an embodiment. The apparatus 100 comprises a radio-frequency circuit device 102. Additionally, the apparatus 100 comprises at least one electrically conducting connection 115 from the top side of the radio-frequency circuit device 102 to at least one terminal means 114. Additionally, the apparatus 100 comprises a flexible substrate 106 having antennas 108_1 and 108_2 in the flexible substrate 106, which are connected to a metallization 116 in an electrically conducting manner, and at least one electrically conducting connection 117 between the terminal means 114 and the metallization 116, wherein the flexible substrate 106 is arranged around the radio-frequency circuit device 102 such that at least one antenna 108_1 is located above the radio-frequency circuit device 102 and at least one antenna 108_2 is located below the radio-frequency circuit device 102.

In embodiments, the layer plane of the antenna can be used for the electrical connection of the antenna, instead of the metallization.

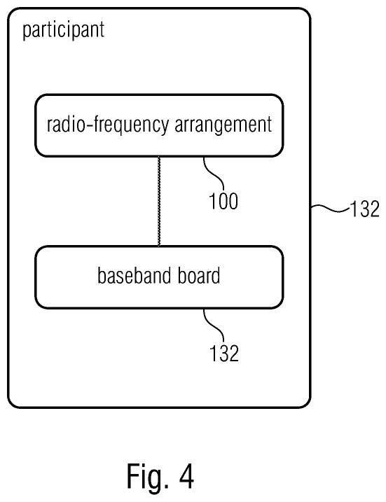

The radio-frequency arrangement 100 described before can, for example, be implemented in a participant of a mobile radio communication system, as is shown exemplarily in FIG. 4.

FIG. 4 shows a schematic block circuit diagram of a participant 130 of a mobile radio communication system (like 3G, LTE or 5G, for example) comprising a radio-frequency arrangement 100 in accordance with an embodiment of the present invention.

In embodiments, the radio-frequency arrangement 100 can be connected to a baseband component 132, like a baseband board, for example, of the participant 130.

The participant 130 can exemplarily be a mobile terminal device (user equipment) or an IoT (Internet of Things) node.

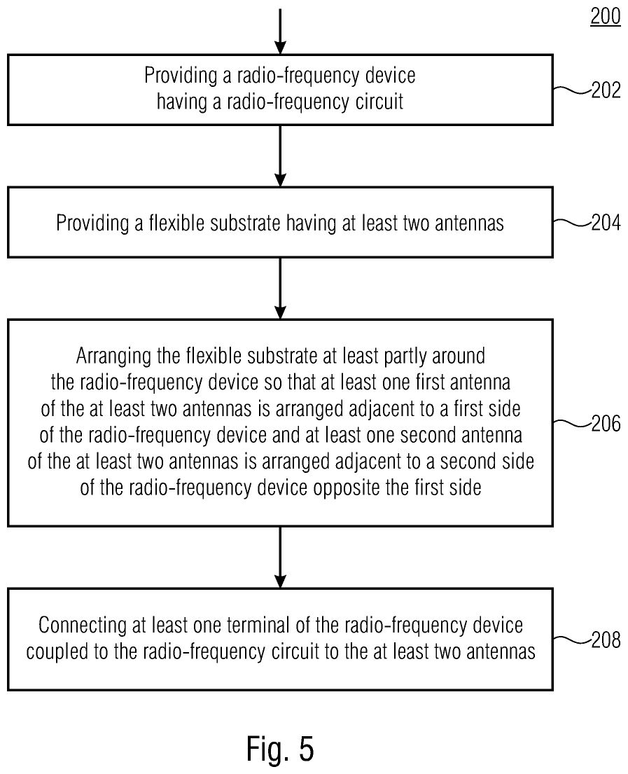

FIG. 5 shows a flow chart of a method 200 for manufacturing a radio-frequency arrangement in accordance with an embodiment of the present invention. The method 200 comprises a step of providing 202 a radio-frequency device 102 having a radio-frequency circuit 104. Additionally, the method 200 comprises a step 204 of providing a flexible substrate 106 having at least two antennas 108_1 and 108_2. Additionally, the method 200 comprises a step 206 of arranging the flexible substrate 106 at least partly around the radio-frequency device 102 so that at least one first antenna 108_1 of the at least two antennas 108_2 is arranged adjacent to a first side 110_1 of the radio-frequency device 102 and at least one second antenna 108_2 of the at least two antennas 108_1 and 108_2 is arranged adjacent to a second side 110_2 of the radio-frequency device 120 opposite the first side 110_1. Additionally, the method 200 comprises a step 208 of connecting at least one terminal 114 of the radio-frequency device 102 coupled to the radio-frequency circuit 104, to the at least two antennas 108_1 and 108_2.

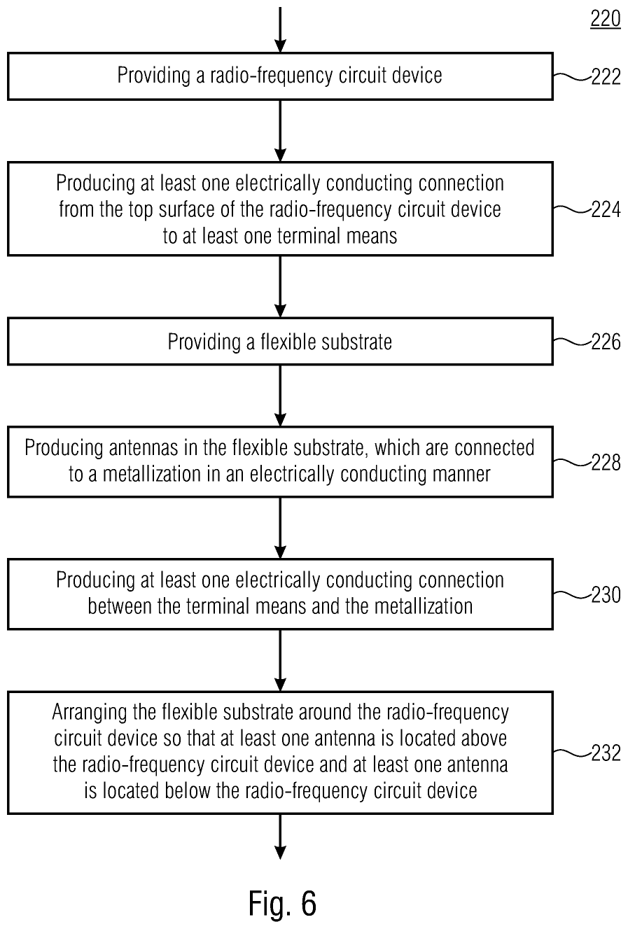

FIG. 6 shows a flow chart of a method 220 for connecting an electrical radio-frequency circuit 102 to an arrangement of antennas 108_1 and 108_2 in accordance with an embodiment of the present invention. The method 220 comprises a step 222 of providing a radio-frequency circuit device 102. Additionally, the method 220 comprises a step 224 of producing at least one electrically conducting connection 115 from the top side of the radio-frequency circuit device 102 to at least one terminal means 114. Additionally, the method 220 comprises a step 226 of providing a flexible substrate 106. Additionally, the method 220 comprises a step 228 of producing antennas 108_1 and 108_2 in the flexible substrate 106, which are connected to a metallization 116 in an electrically conducting manner. Additionally, the method 220 comprises a step 230 of producing at least one electrically conducting connection 117 between the terminal means 114 and the metallization 116. In addition, the method 220 comprises a step 232 of arranging the flexible substrate 106 around the radio-frequency circuit device 102 so that at least one antenna 108_1 is located above the radio-frequency circuit device 102 and at least one antenna 108_2 is located below the radio-frequency circuit device 102.

In embodiments, the layer plane of the antenna 108_1 can also be used for the electrical connection of the antenna 108_1, instead of the metallization 116. This means that the metallization for antenna control can be produced by the same process step as manufacturing the antenna structures.

Although some aspects have been described in connection with an apparatus, it is to be understood that these aspects also represent a description of the corresponding method so that a block or element of an apparatus is to be understood also to be a corresponding method step or feature of a method step. In analogy, aspects described in connection with or as a method step also represent a description of a corresponding block or detail or feature of a corresponding apparatus. Some or all of the method steps can be executed by a hardware apparatus (or using a hardware apparatus), like a microprocessor, a programmable computer or an electronic circuit, for example. In some embodiments, some or several of the most important method steps can be executed by such an apparatus.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### LIST OF REFERENCES

### [1] SystemPlus Report ©2018 by System Plus Consulting I Qualcomm WiGig60 GHz Chipset Smartphone Edition

1. A radio-frequency arrangement comprising:
a radio-frequency device comprising a radio-frequency circuit, and
a flexible substrate comprising at least two antennas,
wherein the radio-frequency circuit is coupled to the at least two antennas, and
wherein the flexible substrate is arranged at least partly around the radio-frequency device, wherein at least one first antenna of the at least two antennas is arranged adjacent to a first side of the radio-frequency device and at least one second antenna of the at least two antennas is arranged adjacent to a second side of the radio-frequency device opposite the first side.

2. The radio-frequency arrangement in accordance with claim 1,
wherein the flexible substrate is bent at least partly around the radio-frequency device.

3. The radio-frequency arrangement in accordance with claim 1,
wherein a first portion of the flexible substrate which comprises the at least one first antenna is arranged adjacent to the first side of the radio-frequency device or abuts on the first side of the radio-frequency device,
wherein a second portion of the flexible substrate which comprises the at least one second antenna is arranged adjacent to the second side of the radio-frequency device or abuts on the second side of the radio-frequency device.

4. The radio-frequency arrangement in accordance with claim 1,
wherein the flexible substrate comprises a metallization,
wherein the radio-frequency circuit is coupled to the at least two antennas via the metallization.

5. The radio-frequency arrangement in accordance with claim 4,
wherein the metallization is arranged in the same layer plane of the flexible substrate as are the at least two antennas,
or wherein the metallization is arranged in a different layer plane of the flexible substrate than the at least two antennas.

6. The radio-frequency arrangement in accordance with claim 4,
wherein the radio-frequency device comprises at least one terminal coupled to the radio-frequency circuit,
wherein the at least one terminal is coupled to the metallization of the flexible substrate.

7. The radio-frequency arrangement in accordance with claim 1,
wherein the radio-frequency device is a radio-frequency board or a radio-frequency IC.

8. A participant of a mobile radio communication system,
wherein the participant comprises a radio-frequency arrangement in accordance with claim 1.

9. A method for manufacturing a radio-frequency arrangement, the method comprising:
providing a radio-frequency device comprising a radio-frequency circuit,
providing a flexible substrate comprising at least two antennas,
arranging the flexible substrate at least partly around the radio-frequency device so that at least one first antenna of the at least two antennas is arranged adjacent to a first side of the radio-frequency device and at least one second antenna of the at least two antennas is arranged adjacent to a second side of the radio-frequency device opposite the first side, and
connecting at least one terminal of the radio-frequency device coupled to the radio-frequency circuit, to the at least two antennas.

10. The method in accordance with claim 9,
wherein, when arranging the flexible substrate at least partly around the radio-frequency device, the flexible substrate is bent at least partly around the radio-frequency device.

11. The method in accordance with claim 9,
wherein, when arranging the flexible substrate at least partly around the radio-frequency device, a first portion of the flexible substrate which comprises the at least one first antenna is arranged adjacent to the first side of the radio-frequency device or abuts on the first side of the radio-frequency device,
wherein, when arranging the flexible substrate at least partly around the radio-frequency device, a second portion of the flexible substrate which comprises the at least one second antenna is arranged adjacent to the second side of the radio-frequency device or abuts on the second side of the radio-frequency device.

12. The method in accordance with claim 9,
wherein, when connecting at least one terminal of the radio-frequency device coupled to the radio-frequency circuit, to the at least two antennas, the at least one terminal of the radio-frequency device is connected to at least one terminal of the flexible substrate coupled to the at least two antennas.

13. The method in accordance with claim 12,
wherein, when connecting at least one terminal of the radio-frequency device coupled to the radio-frequency circuit, to the at least two antennas, an electrically conducting connection is produced between the terminal of the radio-frequency device and the terminal of the flexible substrate.

14. The method in accordance with claim 9,
wherein, when providing the flexible substrate, the at least two antennas are produced in the flexible substrate.

15. The method in accordance with claim 14,
wherein, when providing the flexible substrate, a metallization which is connected to the at least two antennas, is produced in the flexible substrate.

16. The method in accordance with claim 15,
wherein the metallization is produced in the same layer plane of the flexible substrate as are the at least two antennas,
or wherein the metallization is produced in a different layer plane of the flexible substrate than the at least two antennas.

17. The method in accordance with claim 15,
wherein, when providing the flexible substrate, a connection is produced between at least one terminal of the flexible substrate and the metallization.
